(19) United States
(12) Patent Application Publication
(10) Pub. No.: US 2019/0123231 A1
(43) Pub. Date: Apr. 25, 2019

(54) OPTOELECTRONIC INTEGRATED SEMICONDUCTOR MODULE AND METHOD FOR MANUFACTURING SAME

(71) Applicant: KABUSHIKI KAISHA TOSHIBA, Tokyo (JP)

(72) Inventor: Hideto FURUYAMA, Yokohama (JP)

(73) Assignee: KABUSHIKI KAISHA TOSHIBA, Tokyo (JP)

(21) Appl. No.: 15/917,233

(22) Filed: Mar. 9, 2018

(30) Foreign Application Priority Data
Oct. 20, 2017 (JP) 2017-203443

(51) Int. Cl. H01L 31/167; H01L 31/0232; H01L 33/58; H01L 33/62

(52) U.S. Cl. CPC H01L 31/167; H01L 33/62; H01L 33/58; H01L 31/0232

(57) ABSTRACT

According to one embodiment, the electric interconnection layer includes a metal interconnection and an insulating film. The optical device is provided within the electric interconnection layer, and electrically connected to the metal interconnection. The optical device includes at least one of a light emitting element and a light receiving element. The optical waveguide is provided within the electric interconnection layer, and optically coupled to the optical device. The semiconductor devices are provided on a first face of the electric interconnection layer, and electrically connected to the metal interconnection. The resin seals the semiconductor devices. The external connection terminals are provided on a second face of the electric interconnection layer, and electrically connected to the metal interconnection.

### CROSS-REFERENCE TO RELATED APPLICATION

This application is based upon and claims the benefit of priority from Japanese Patent Application No. 2017-203443, filed on Oct. 20, 2017; the entire contents of which are incorporated herein by reference.

### FIELD

Embodiments described herein relate generally to an optoelectronic integrated semiconductor module and a method for manufacturing an optoelectronic integrated semiconductor module.

### BACKGROUND

Research is in progress into optically connected high-performance optoelectronic silicon interposer. The optoelectronic silicon interposer includes, for example, a plurality of similar or dissimilar large-scale integrated circuits (LSIs) such as a central processing unit (CPU) and a memory element mounted on a silicon substrate.

### BRIEF DESCRIPTION OF THE DRAWINGS

FIG. 1A to FIG. 4B are schematic cross-sectional views illustrating a method for manufacturing an optoelectronic integrated semiconductor module according to an embodiment;

FIG. 5A is a schematic cross-sectional view of an optical device and optical waveguide according to an embodiment, and FIG. 5B is a schematic plan view illustrating an optical device and optical waveguide according to an embodiment;

FIG. 6A to FIG. 9B are schematic cross-sectional views illustrating a method for manufacturing an optoelectronic integrated semiconductor module according to an embodiment;

FIG. 10A is a schematic cross-sectional view of a light receiving element according to an embodiment, and FIGS. 10B and 10C are schematic plan views of a light receiving element according to an embodiment;

FIG. 11A is a schematic cross-sectional view of a light emitting element according to an embodiment, and FIG. 11B is a schematic plan view of a light emitting element according to an embodiment;

FIG. 12A is a schematic cross-sectional view of a light emitting element according to an embodiment, and FIG. 12B is a schematic plan view of a light emitting element according to an embodiment;

FIG. 13A is a schematic cross-sectional view of a light receiving element according to an embodiment, and FIGS. 13B and 13C are schematic plan views of a light receiving element according to an embodiment;

FIG. 14A is a schematic cross-sectional view of an optical device and optical waveguide according to an embodiment, and FIG. 14B is a schematic plan view of an optical device and optical waveguide according to an embodiment;

FIG. 15A is a schematic cross-sectional view of a light receiving element according to an embodiment, and FIGS. 15B and 15C are schematic plan views of a light receiving element according to an embodiment;

FIG. 16A is a schematic cross-sectional view of an optical device and optical waveguide according to an embodiment, and FIG. 16B is a schematic plan view illustrating an optical device and an optical waveguide according to an embodiment;

FIG. 17A is a schematic cross-sectional view of a light receiving element according to an embodiment, and FIGS. 17B and 17C are schematic plan views of a light receiving element according to an embodiment;

FIG. 18A to FIG. 20B are schematic cross-sectional views illustrating a method for manufacturing an optoelectronic integrated semiconductor module according to an embodiment;

FIG. 21A is a schematic cross-sectional view of a light emitting element according to an embodiment, and FIG. 21B is a schematic cross-sectional view of a light emitting element according to an embodiment;

FIG. 22A to FIG. 26B are schematic cross-sectional views illustrating a method for manufacturing an optoelectronic integrated semiconductor module according to an embodiment; and

FIG. 27 and FIG. 28 are schematic cross-sectional views of an optoelectronic integrated semiconductor module and mounting board according to an embodiment.

### DETAILED DESCRIPTION

According to one embodiment, an optoelectronic integrated semiconductor module includes an electric interconnection layer, an optical device, an optical waveguide, a plurality of semiconductor devices, a resin, and a plurality of external connection terminals. The electric interconnection layer includes a metal interconnection and an insulating film. The optical device is provided within the electric interconnection layer, and electrically connected to the metal interconnection. The optical device includes at least one of a light emitting element and a light receiving element. The optical waveguide is provided within the electric interconnection layer, and optically coupled to the optical device. The semiconductor devices are provided on a first face of the electric interconnection layer, and electrically connected to the metal interconnection. The resin seals the semiconductor devices.

The external connection terminals are provided on a second face of the electric interconnection layer, and electrically connected to the metal interconnection.

Embodiments will be described below with reference to drawings. Note that the same reference numerals are applied to the same elements in each drawing.

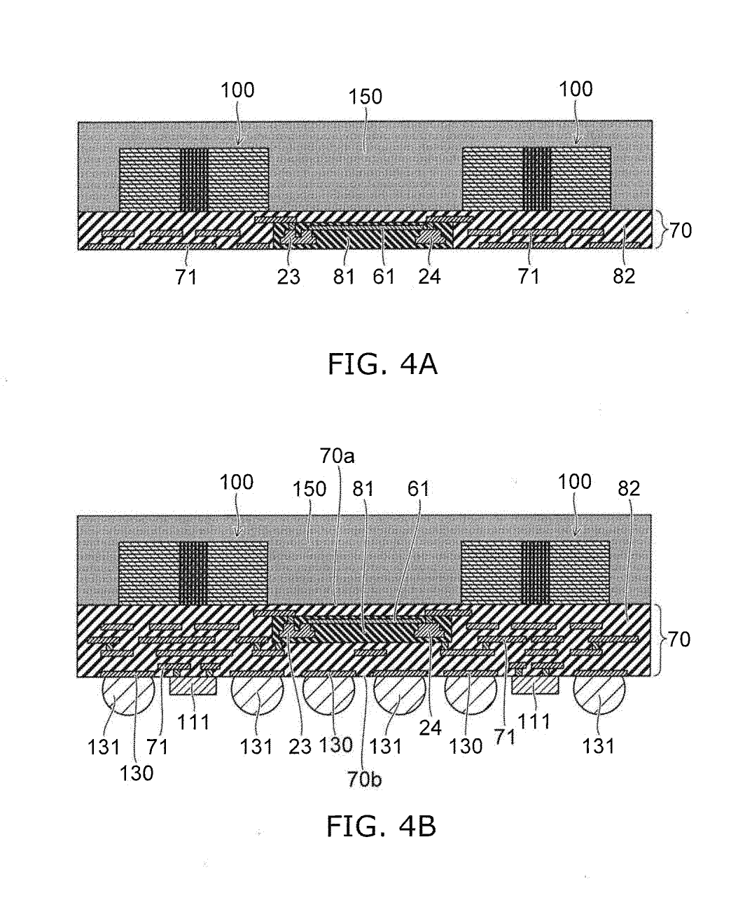

FIG. 4B is a schematic cross-sectional view illustrating an optoelectronic integrated semiconductor module according to an embodiment.

The optoelectronic integrated semiconductor module illustrated in FIG. 4B includes an electric interconnection layer (or re-distribution layer (RDL)) 70, a plurality of semiconductor devices 100 mounted on the electric interconnection layer 70, and resin 150 that seals the semiconductor devices 100.

The electric interconnection layer 70 includes a metal interconnection 71 and an insulating film 82. The metal interconnection 71 is, for example, copper interconnection, and the insulating film 82 insulates between the metal interconnection 71. The metal interconnection layer 70 includes a first face 70a and a second face 70b. For example, the second face 70b is the face opposite to the first face 70a.

The semiconductor devices 100 are mounted on the first face 70a of the electric interconnection layer 70, and are electrically connected to the metal interconnection 71. A plurality of external connection terminals 130 electrically connected to the metal interconnection 71 is provided on the second face 70b of the electric interconnection layer 70. The external connection terminals 130 are, for example, pad electrodes. For example, solder balls 131 or the like can be bonded to the external connection terminals 130.

Also, a semiconductor device 111 is mounted on the second face 70b of the electric interconnection layer 70. The semiconductor device 111 is electrically connected to the metal interconnection 71. For example, the semiconductor devices 100 include a memory chip, and the semiconductor device 111 includes a control circuit that controls the memory chip. The semiconductor device 111 may be integrated with the semiconductor device 100.

Optical devices and an optical waveguide 61 are provided within the electric interconnection layer 70. For example, the peripheries of the optical devices and optical waveguide 61 are surrounded by the insulating film 82 of the electric interconnection layer 70. The optical devices include a light emitting element 23 and a light receiving element 24. The light emitting element 23 and the light receiving elements 24 are electrically connected to the metal interconnection 71, and are optically coupled to the optical waveguide 61 within the electric interconnection layer 70. The light emitting element 23 and the light receiving element 24 may also include a portion provided outside the electric interconnection layer 70.

The optical waveguide 61 functions as an optical waveguide core provided within an insulating film 81, and the insulating film 81 functions as optical confinement cladding. For example, the optical devices are provided within the insulating film 81, and the insulating film 81 is provided within the insulating film 82. The periphery of the insulating film 81 is surrounded by the insulating film 82.

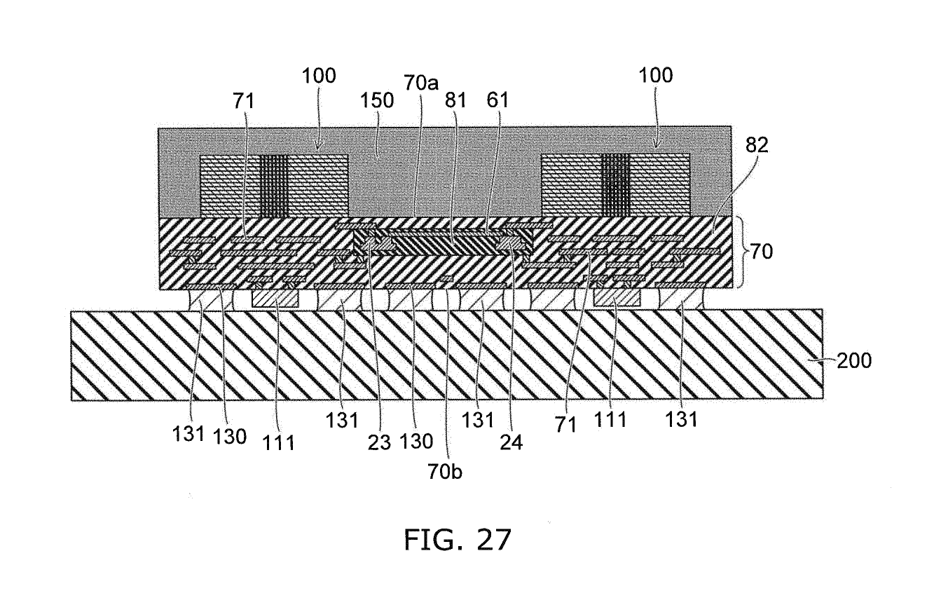

As illustrated in FIG. 27, the optoelectronic integrated semiconductor module is mounted on a mounting board (circuit board) 200 via the solder balls 131 connected to the external connection terminals 130. Also, the optoelectronic integrated semiconductor module may be mounted on the mounting board 200 without the use of solder balls. The solder balls 131 are electrically connected to electric interconnection formed on the mounting board 200. Power or signals from the exterior are applied to the semiconductor devices 111, 100 through the solder balls 131, external connection terminals 130, and metal interconnection 71.

For example, a portion of the signal line between the external connection terminals 130 and the semiconductor device 111 is an optical interconnection. The light emitting element 23 converts an electrical signal input from the external connection terminals 130 into a light signal, and the light signal is transmitted to the light receiving element 24 via the optical waveguide 61. The light receiving element 24 converts the light signal into an electrical signal, and the semiconductor device 111 is driven and controlled by the electrical signal. In addition, a memory chip of the semiconductor device 100 is driven and controlled by an electrical signal from the semiconductor device 111.

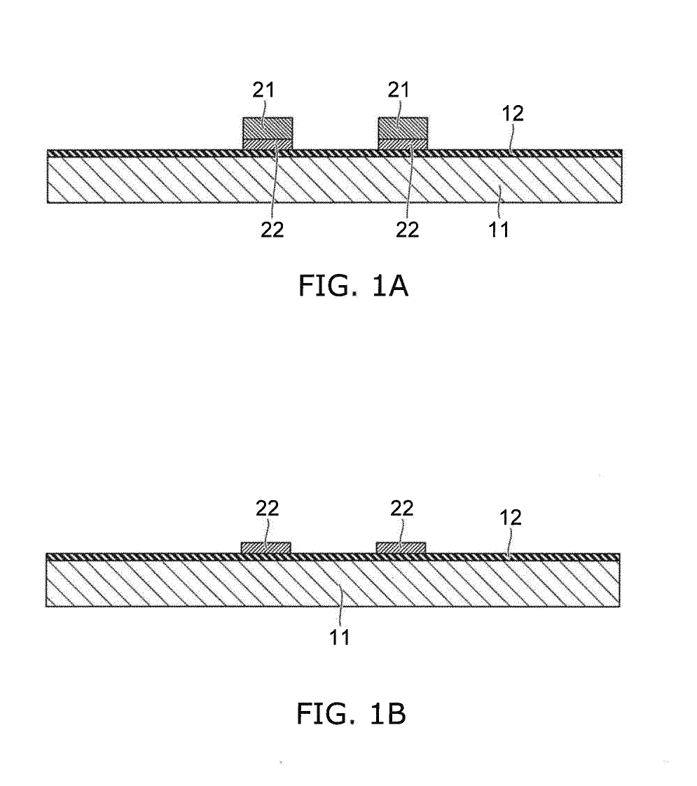

Next, a method for manufacturing the optoelectronic integrated semiconductor module illustrated in FIG. 4B is described with reference to FIG. 1A to FIG. 4B.

As illustrated in FIG. 1A, an optical device material 22 is formed on a support member 11. The support member 11 is, for example, a silicon substrate or a glass substrate.

The optical device material 22 is, for example, an epitaxial growth layer of a group III-V compound semiconductor. The optical device material 22 is bonded to the support member 11 together with a substrate 21 on which the optical device material 22 has been epitaxially grown, either in wafer form or in the form of chips separated into individual pieces.

The optical device material 22 is directly bonded to the support member 11. Alternatively, the optical device material 22 can be bonded to the support member 11 via an oxide film (or an adhesive layer) 12.

When the support member 11 is a silicon substrate, the optical device material 22 may be formed by epitaxial growth on the silicon substrate.

The substrate 21 on which the optical device material 22 was epitaxially grown is removed, as illustrated in FIG. 1B. Also, the substrate 21 may remain.

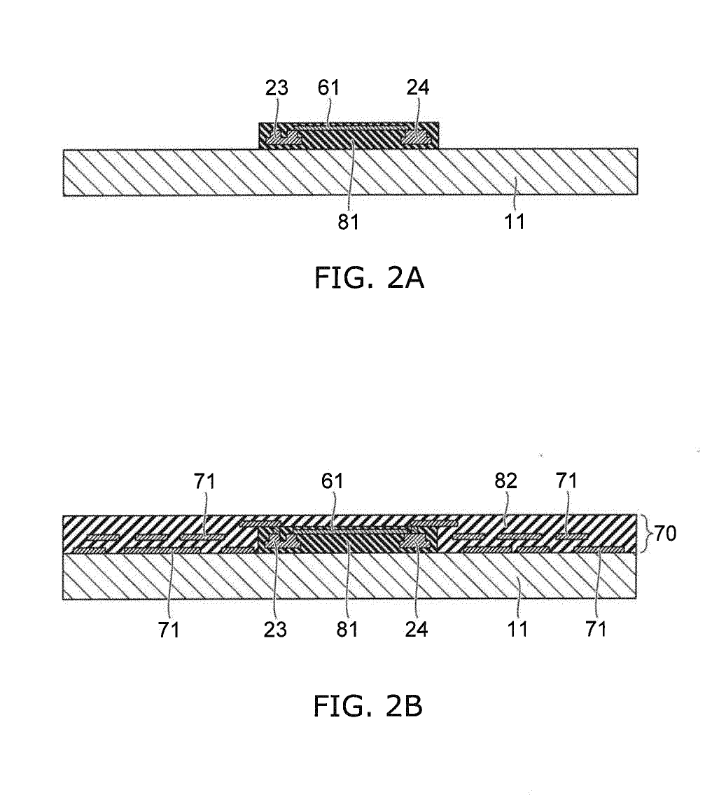

Next, the light emitting element 23 and the light receiving element 24 are formed by processing of the optical device material 22 and forming electrodes and the like on the support member 11, as illustrated in FIG. 2A. At the same time or subsequently, the optical waveguide 61 is formed.

The light emitting element 23, the light receiving element 24, and the optical waveguide 61 are formed within the insulating film 81. The light emitting element 23 and the light receiving element 24 are optically coupled to the optical waveguide 61.

Next, the electric interconnection layer 70 is formed on the support member 11, as illustrated in FIG. 2B. The electric interconnection layer 70 includes a metal interconnection 71 either as a single layer or multiple layers, and the interlayer insulating film 82.

The metal interconnection 71 is, for example, Cu interconnection, formed by a semi-additive method. The interlayer insulating film 82 is, for example, a polyimide resin, an epoxy resin, a silicone resin, or the like.

The light emitting element 23 and the light receiving element 24 are electrically connected to the metal interconnection 71. A portion of the electric interconnection layer 70 forms an optical interconnection structure that includes the light emitting element 23, the light receiving element 24, and the optical waveguide 61.

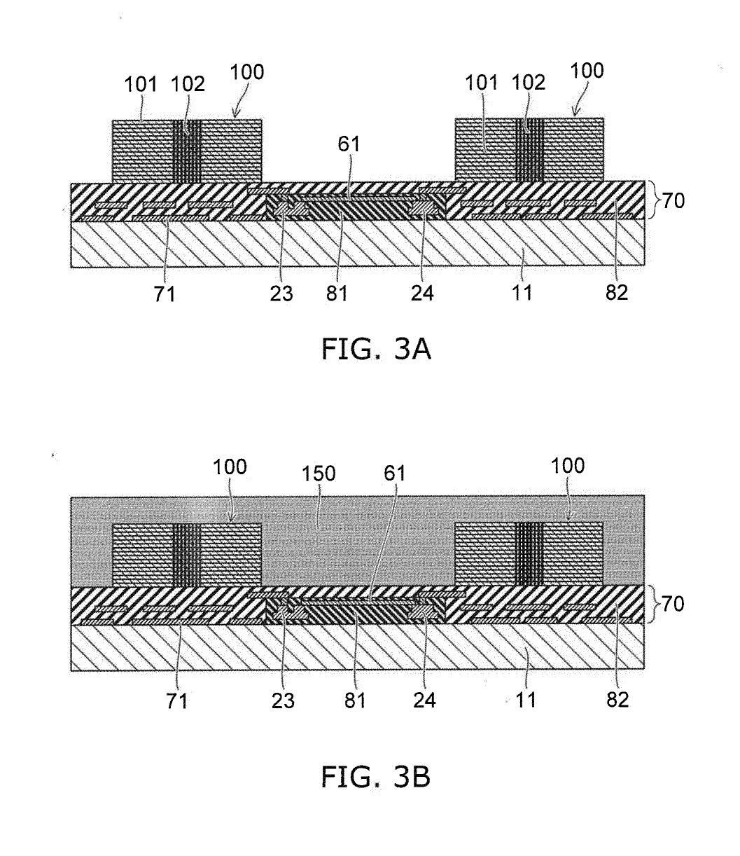

Next, the semiconductor devices 100 is mounted on the electric interconnection layer 70, as illustrated in FIG. 3A. The semiconductor devices 100 are electrically microbump-connected to the metal interconnection 71 by, for example, reflow connection with small solder balls, or ultrasonic bonding using Au stud bumps.

The semiconductor devices 100 have a three-dimensional integrated LSI structure in which a plurality of semiconductor chips (for example memory chips) 101 is stacked. The plurality of semiconductor chips 101 is connected using through electrodes 102 such as through silicon vias (TSVs).

A stacked body including the stacked semiconductor chips 101 connected by TSVs may be mounted on the electric interconnection layer 70, or a stacked body including the stacked chips may be formed by successively stacking thin chips with TSVs onto the electric interconnection layer 70.

After the semiconductor devices 100 are mounted, the semiconductor devices 100 are sealed with mold resin 150, as illustrated in FIG. 3B. The resin 150 is applied to the whole face on which the semiconductor devices 100 are mounted, to cover the semiconductor devices 100.

The resin 150 is, for example, an epoxy resin, a silicone resin or the like, adjusted by adding silica filler so that the thermal expansion coefficient is the same as the thermal expansion coefficient of the support member 11.

After forming the resin 150, the support member 11 is removed. For example, the support member 11 is mechanically separated by forming in advance a temporary bonding member of organic material or inorganic material on the face on which the electric interconnection layer 70 is formed on the support member 11, and inserting a knife edge into the temporary bonding member. Also, the temporary bonding member can be heated and foamed to separate the support member 11. Also, the temporary bonding member can be separated from the support member 11 by irradiating the temporary bonding member with a laser to be degraded. Also, the support member 11 may be removed by grinding or selectively etching, or the like.

When the support member 11 is removed, the second face of the electric interconnection layer 70 (the face opposite the first face on which the semiconductor devices 100 are mounted) is exposed. The plurality of external connection terminals (for example, pad electrodes) 130 is formed on the exposed second face of the electric interconnection layer 70, as illustrated in FIG. 4B. Solder balls 131 or the like may be formed on the external connection terminals 130. Also, additional metal interconnection 71 may be formed on the electric interconnection layer 70.

Semiconductor devices (controller chip, interface chip, and the like) 111 that are separate from the semiconductor devices 100 of the first face 70a are mounted on the second face 70b of the electric interconnection layer 70. Also, passive components such as condensers may also be mounted on a portion of the second face 70b of the electric interconnection layer 70. The semiconductor device 111 may be integrated with the semiconductor device 100.

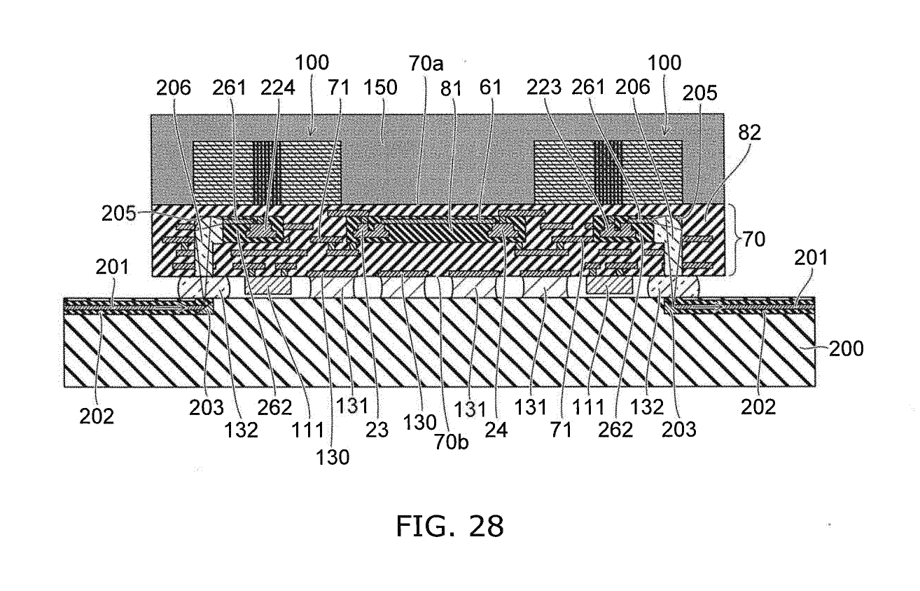

Also, as illustrated in FIG. 28, optical connection terminals (for example, silicone resin balls or the like) 132 can be formed on the second face 70b of the electric interconnection layer 70.

The optical connection terminals 132 are optical paths that optically couple the light emitting element 23, the light receiving element 24, and the optical waveguide 61 with optical devices and optical waveguides 201 formed on the mounting board 200. Such an optoelectronic integrated module is optically connected to the exterior via the optical connection terminals 132.

The optical waveguides 201 that function as an optical waveguide core are formed in the mounting board 200. The optical waveguides 201 are formed within an insulating film 202 that functions as optical confinement cladding. Also, a 45° angle of incidence mirror 203 is formed in the mounting board 200.

The optical devices (light emitting element 23, light receiving element 24), the optical waveguide 261 that functions as optical waveguide core, an insulating film 262 that functions as optical confinement cladding, an optical waveguide 206, and a concave 45° angle of incidence mirror 205 are provided within the electric interconnection layer 70.

The optical connection terminals 132 are optically coupled to the optical waveguides 201 of the mounting board 200 via a 45° mirror 203. Also, the optical connection terminals 132 are optically coupled to the optical waveguide 206 within the electric interconnection layer 70.

A light emitting element 223 and a light receiving element 224 are optically coupled to the optical waveguide 261, and electrically connected to the metal interconnection 71. The optical waveguide 261 is optically coupled to the optical waveguide 206.

The light emitting element 223 can have the same configuration as the light emitting element 23 and can be formed at the same time as the light emitting element 23. The light receiving element 224 can have the same configuration as the light receiving element 24 and can be formed at the same time as the light receiving element 24.

The same material as used in the optical waveguide 61 can be used for the optical waveguides (cores) 261, 201. The same material as used in the insulating film 81 can be used for the insulating film (cladding) 262, 202. The optical waveguide 261 can be formed at the same time as the optical waveguide 61. The insulating film 262 can be formed at the same time as the insulating film 81.

The optical waveguide 206 can be formed from, for example, a transparent resin (silicone, epoxy, polyimide, polycarbonate, polypropylene terephthalate), silicon oxide, or a quartz formed item, for example in a prismatic shape. Also, a cavity may be provided within the optical waveguide 206.

The mirrors 203, 205 can be formed from a metal such as Au, Al, Ni, Ag. Also, the optical waveguide 206 may be formed from, for example, a transparent resin, silicon oxide, or a quartz formed item, with the mirror 205 portion as a cavity, with a totally reflecting mirror using total reflection at the boundary thereof. For example, when the optical waveguide 206 is made from a material with refractive index 1.5, the angle of incidence of the light at the boundary between the optical waveguide 206 and the cavity (air) is 48° or greater.

In the example of FIG. 28, the light guided through the optical waveguide 201 on the left side of the mounting board 200 is reflected at the mirror 203, guided upwards through the optical connection terminal 132 and the optical waveguide 206, reflected and focused at the mirror 205, and is incident on the optical waveguide 261. Then, the light receiving element 224 receives the light input from the optical waveguide 261, and provides an electrical output to the metal interconnection 71.

Also, the light emitting element 223 that receives the electrical signal input from the metal interconnection 71 outputs light toward the optical waveguide 261, the light is reflected by the mirror 205, guided downward through the optical waveguide 206 and the optical connection terminal 132 toward the mirror 203 so as to form an image, the light is further reflected at the mirror 203 and output toward the optical waveguide 201 of the mounting board 200.

According to the embodiment as described above, a high-speed connection with an optical interconnection and power supply/low speed connection with the metal interconnection 71 can be configured from low cost resin mold as the basis. A high cost mounting substrate such as a silicon interposer with TSVs is not used, so low cost can be easily achieved with high function. Also, a large scale panel level batch forming process in the order of meters is enabled, for example, large scale semiconductor modules of 5 cm×5 cm or larger can be easily mass-produced, so high performance low cost large scale optoelectronic integrated semiconductor modules can be realized.

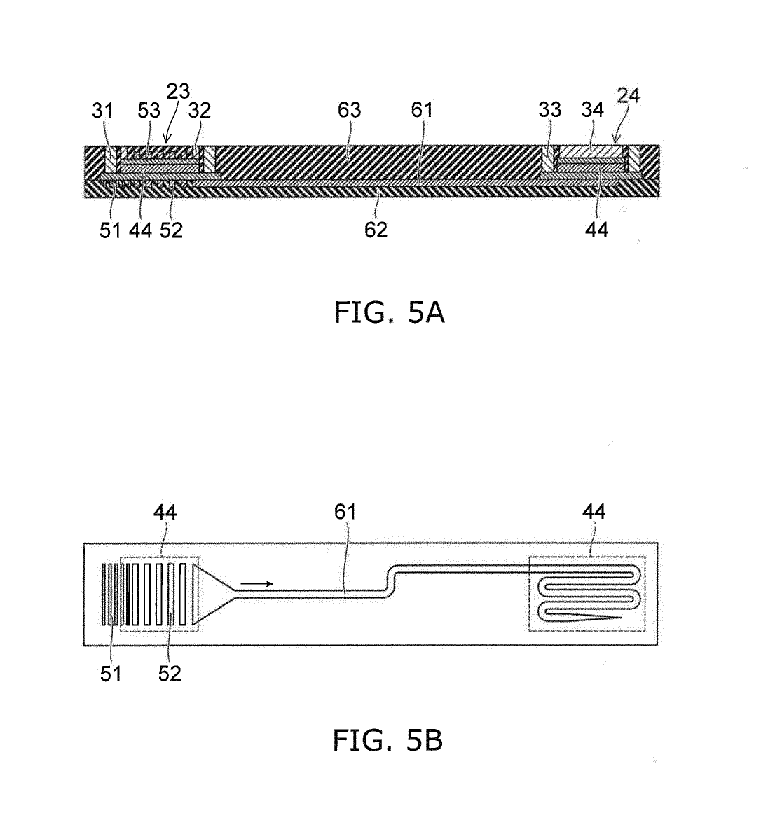

FIG. 5A is a schematic cross-sectional view illustrating an example of an optical interconnection structure portion according to an embodiment, and FIG. 5B is a schematic plan view thereof.

The optical waveguide (core) 61 is provided between an insulating film 62 that functions as cladding and an insulating film 63 that functions as cladding. For example, the insulating film 62 is a silicon oxide film (SiO₂ film), and the insulating film 63 is a silicon oxide film or a resin film. The optical waveguide 61 is an amorphous silicon film, a polysilicon film, a silicon nitride film, or a silicon oxynitride film.

The light emitting element 23 and the light receiving element 24 are optically coupled to the optical waveguide 61. For example, the light emitting element 23 is a membrane reflector vertical cavity surface emitting laser diode (MR-VCSEL), and the light receiving element 24 is a p-i-n photo diode (pin-PD).

The light emitting element (MR-VCSEL) 23 includes a group III-V epitaxial growth layer 44 that includes a multi quantum well (MQW), a high contrast grating (HCG) coupler 52, a distributed Bragg reflector (DBR) 51, a high contrast grating (HCG) mirror 53, a p-side electrode 32, and an n-side electrode 31.

The HCG coupler 52, the DBR 51, and the HCG mirror 53 are formed from, for example, amorphous silicon or polysilicon.

The light receiving element (pin-PD) 24 includes, for example, the group III-V epitaxial growth layer 44 that includes an MQW, a p-side electrode 34, and an n-side electrode 33.

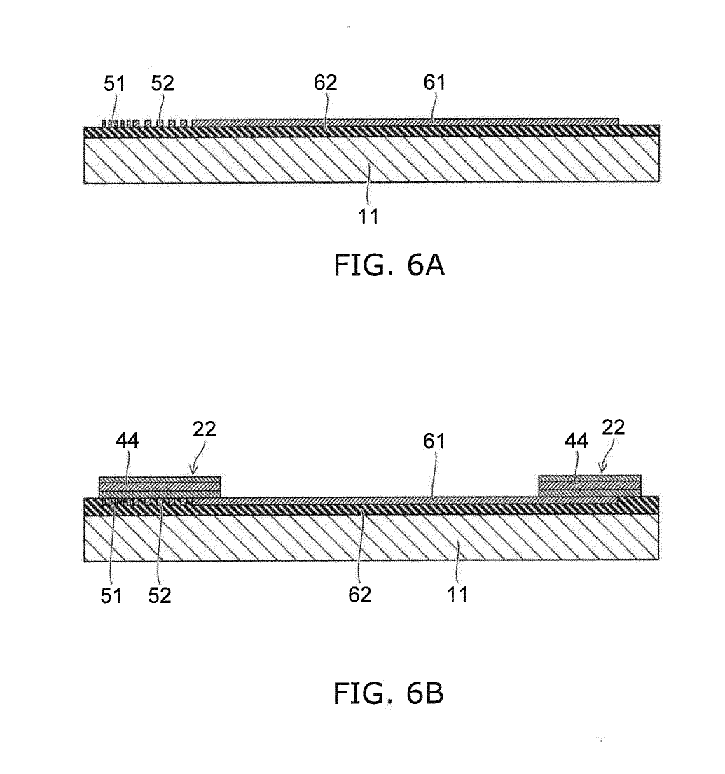

Next, a method for forming the structure illustrated in FIGS. 5A and 5B is described with reference to FIG. 6A to FIG. 9B.

Thermal oxidation is performed on a surface of, for example, a silicon substrate as the support member 11, to form the insulating film 62 as a silicon oxide film (SiO₂ film) on the surface of the support member 11, as illustrated in FIG. 6A. Alternatively, the insulating film 62 is formed as a silicon oxide film (SiO₂ film) by chemical vapor deposition (CVD).

A silicon film (amorphous silicon film or polysilicon film) is formed on the insulating film 62 by CVD, and then a patterning process is performed on the silicon film to form the optical waveguide 61, the HCG coupler 52, and the DBR 51.

Then, a silicon oxide film is formed over the whole surface, the pattern (optical waveguide 61, HCG coupler 52, DBR 51) of the silicon film is filled with the silicon oxide film, and flattened by chemical mechanical polishing (CMP). A thin silicon oxide film (not illustrated on the drawings) remains as a core cover. Also, after the processes illustrated in FIG. 6A, a thin silicon oxide film, a thin silicon nitride film, and a buried silicon oxide film may be formed, and CMP may be performed using a silicon nitride film as a stopper.

Then, as illustrated in FIG. 6B, the optical device material (group III-V compound semiconductor epitaxial growth layer) 22 is attached to the support member 11 on which the silicon oxide pattern as described above (optical waveguide 61, HCG coupler 52, DBR 51) has been formed.

The optical device material 22 is attached to the whole face of the support member 11. Alternatively, the optical device material 22 is attached in the form of a chip having area added to the optical device region as a margin for positional deviation/processing allowance.

The optical device material 22 may be attached as a thin film chip separated from the substrate on which it was grown epitaxially, or it may be attached to each growth substrate. After attaching the optical device material 22 to each growth substrate, the growth substrate can be polished to form a thin layer, or the growth substrate can be removed by etching.

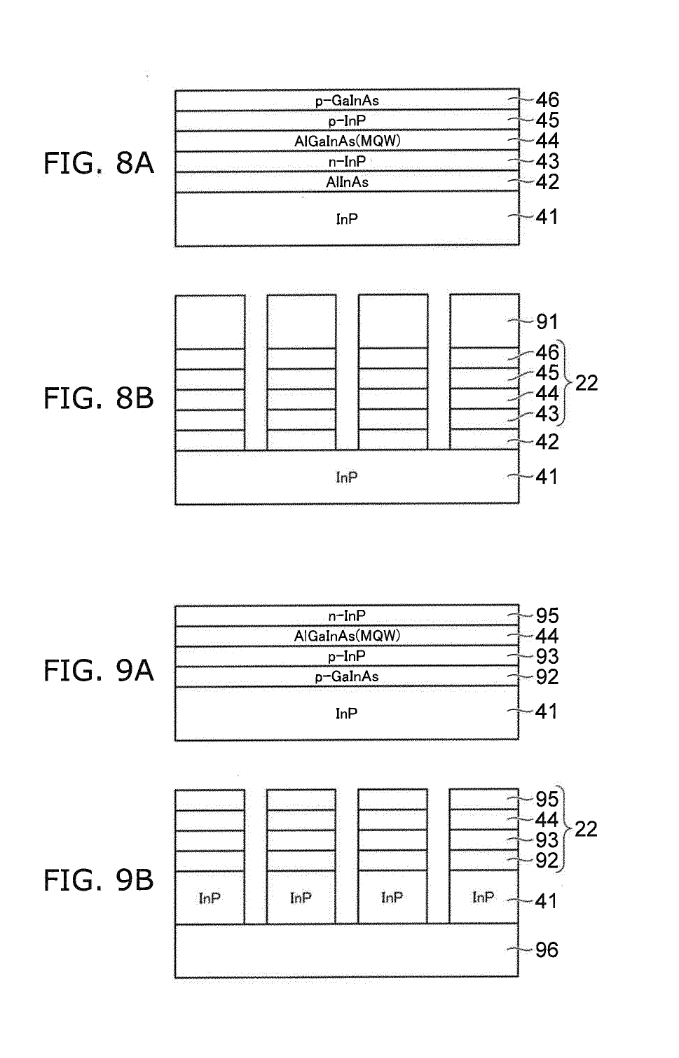

FIGS. 8A and 8B illustrate examples of the optical device material 22.

As illustrated in FIG. 8A, an AlInAs peeling layer 42, an n-type InP cladding layer 43, an AlGaInAs MQW layer (for example, light emission wavelength 1.3 μm) 44, a p-type InP cladding layer 45, and a p-type GaInAs contact layer 46 are grown in that order on an InP substrate 41.

A dry film resist 91 having a thickness of, for example, 30 μm is applied to the epitaxial growth layer, as illustrated in FIG. 8B. The dry film resist 91 is patterned by exposing the dry film resist 91 to light and developing. The dry film resist 91 is patterned into a plurality of island shapes with a predetermined size (for example, 0.3 mm×0.3 mm) separated by grooves of 50 μm width.

Mesa etching is performed on the epitaxial growth layer using the patterned dry film resist 91 as a mask. As illustrated in FIG. 8B, from the p-type GaInAs contact layer 46 to the AlInAs peeling layer 42 are separated by etching. The InP substrate 41 not separated can be reused.

Then, in a case where the AlInAs peeling layer 42 is selectively removed by side etching with a hydrofluoric acid etchant, optical device material chips in which the optical device material (group III-V compound semiconductor epitaxial growth layer) 22 is held on the dry film resist 91 can be obtained in individual pieces. Then, the dry film resist 91 portions can be picked up, and the optical device material 22 can be bonded to a predetermined position on the support member 11.

In a case where the surfaces are cleaned, bonding can be performed through the intermolecular forces between the surface of the optical device material 22 and the surface on the support member 11 side (in the above example, the surface of the thin SiO₂ film that has been subjected to CMP). More positively, bonding can be performed via hydroxide groups by a hydrophilization process, or thin oxide films can be bonded together by an oxygen plasma process.

After the optical device material 22 has been applied to the support member 11, the dry film resist 91 is removed by cleaning.

FIGS. 9A and 9B illustrate another example of the optical device material 22.

As illustrated in FIG. 9A, a p-type GaInAs contact layer 92, a p-type InP cladding layer 93, the AlGaInAs MQW layer (for example, light emission wavelength 1.3 μm) 44, and an n-type InP cladding layer 95 are grown in that order on the InP substrate 41.

As illustrated in FIG. 9B, the wafer is applied to a dicing film 96 and diced, and separated into individual pieces in an island shape with a predetermined size (for example, 0.3 mm×0.3 mm).

Then, the surfaces of the n-type InP cladding layer 95 are cleaned, and bonded to a predetermined position on the support member 11. In the case where the surfaces are cleaned, then bonding can be performed through the intermolecular forces between the surface of the n-type InP cladding layer 95 and the surface on the support member 11 side (in the above example, the surface of the thin SiO₂ film that has been subjected to CMP). More positively, bonding can be performed via hydroxide groups by a hydrophilization process, or thin oxide films can be bonded together by an oxygen plasma process.

After applying the optical device material 22 to the support member 11, the InP substrate 41 is removed with, for example, a selective etchant such as hydrochloric acid.

As illustrated in FIG. 6B, the optical device material 22 applied to the support member 11 is patterned and etched so that at least the region necessary for the optical devices remains.

In the examples illustrated in FIGS. 8A and 8B, the p-type GaInAs layer 46, the p-type InP layer 45, and the MQW layer 44 are patterned and etched in the optical device material 22, and the portions in contact with the n-side electrode are exposed in the n-type InP layer 43. Then, the optical device material 22 is embedded in an insulating film (for example, a silicon oxide film) 63a, and flattened by CMP. A thin silicon oxide film remains as a cover film on the surface of the p-type GaInAs layer 46. Also, a thin silicon oxide film, a thin silicon nitride film, and a buried silicon oxide film may be formed, and CMP may be performed using a silicon nitride film as a stopper. Also, the optical device material 22 may be embedded in a resin such as polyimide, instead of the silicon oxide film.

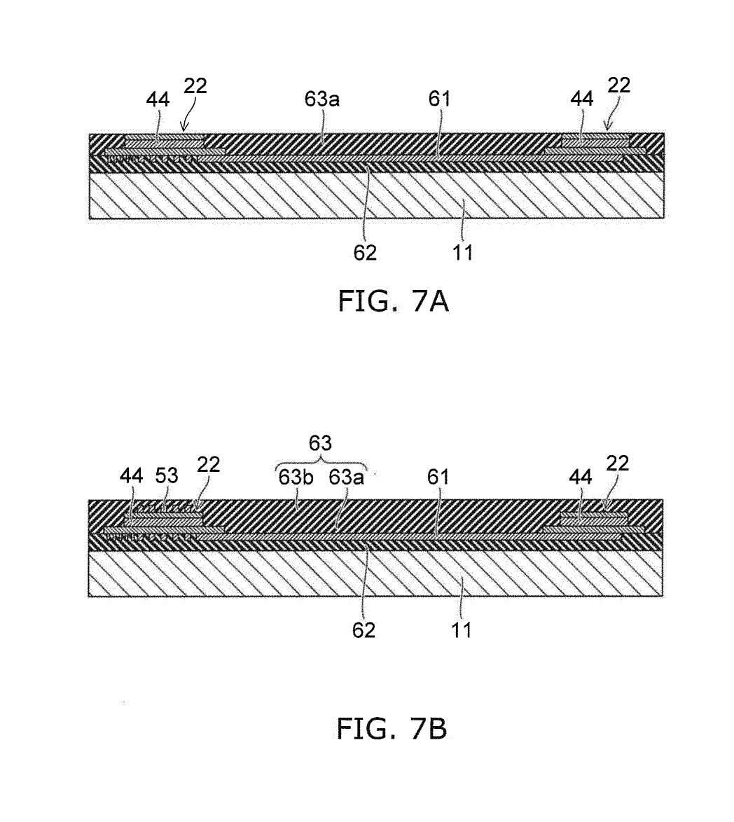

Then, a silicon film (amorphous silicon film or polysilicon film) is formed by CVD on the surface of the structural body illustrated in FIG. 7A. The silicon film is patterned, and the HCG mirror 53 is formed on the top side of the MR-VCSEL part, as illustrated in FIG. 7B. The silicon film of the pin-PD part is completely removed.

Then, the MR-VCSEL part and the pin-PD part are embedded in the insulating film (for example, silicon oxide film) 63b, and the insulating film 63b is flattened.

Then, an opening is formed in the insulating film 63, and electrode metal (Ti/Pt/Au, or the like) is formed within the opening. In this way, the p-side electrode 32 of the light emitting element (MR-VCSEL) 23, the n-side electrode 31, the p-side electrode 34 of the light receiving element (pin-PD) 24, and the n-side electrode 33 are formed, as illustrated in FIG. 5A.

When a forward bias is applied, the light emitting element (MR-VCSEL) 23 is energized and emits light thereby causing laser oscillation. When a reverse bias is applied to the light receiving element (pin-PD) 24, a band edge shift is caused by a quantum confined stark effect (QCSE) of the MQW 44. Such a pin-PD can absorb a wavelength corresponding to the light emission wavelength when a forward bias is applied.

According to the embodiment, by using the same optical device material 22 (epitaxial growth layer that includes the MQW), it is possible to form both the light emitting element 23 and the light receiving element 24 on the same support member 11. This enables material and processes to be reduced. In addition, such reducing the material and processes enables the yield and reliability to be improved, and major cost reductions to be made.

Also, by transferring the optical devices onto the support member 11 in the semi-completed state, the process of completion of the optical devices is performed on the support member 11, so even in a case where deviation in the transfer positional accuracy is caused, the active regions of the optical devices themselves can be formed in their proper location.

The HCGs 52, 53 in the light emitting element (HR-VCSEL) 23 have a period in which the laser resonance wavelength (wavelength within the waveguide: shortened by the equivalent refractive index) is corrected by the thickness of the HCG. For example, in a case where the laser resonance wavelength λ is 1.3 μm, the thickness of the silicon HCG is 400 nm, and the embedding film is SiO₂, then the HCG period is 550 nm.

Such an MR-VCSEL laser resonates in the vertical direction, and with the HCG, can emit light in the horizontal direction.

The DBR 51 reflects the laser light output in the horizontal direction by the HCG. By providing the DBR 51 on one side only, the light output direction can be limited.

The DBR 51 has a period in which the laser resonance wavelength (wavelength within the waveguide: shortened by the equivalent refractive index) is ½ or 3/2 of the period corrected by the thickness of the HCG. For example, in a case where the laser resonance wavelength λ is 1.3 μm, the thickness of the silicon HCG is 400 nm, and the embedding film is SiO₂, then the DBR 51 period is 275 nm.

The light emitting element 23 is not limited to the MR-VCSEL, but for example, can be a ring laser.

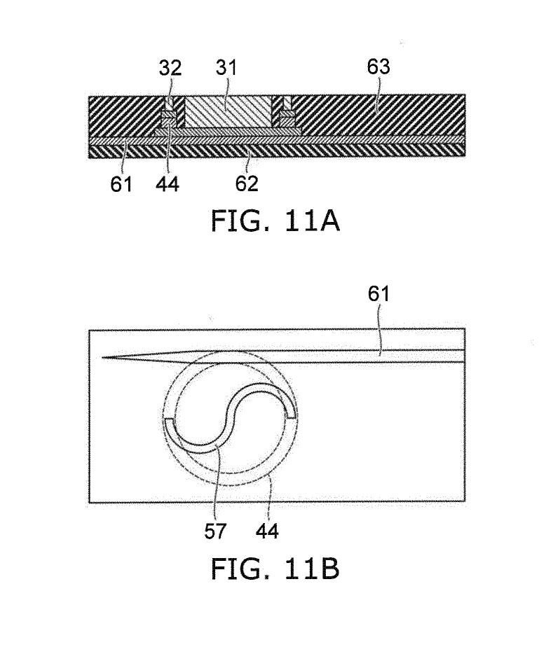

FIG. 11A is a schematic cross-sectional view of a ring laser (ring cavity laser diode with loop mode filter), and FIG. 11B is a schematic plan view of the ring laser.

An S-shaped feedback waveguide 57 and a linear output waveguide 61 are formed between the insulating film 62 and the insulating film 63. The feedback waveguide 57 and the output waveguide 61 are silicon films (amorphous silicon film or polysilicon film).

The semiconductor layer that includes the MQW active layer 44 and the p-side electrode 32 are formed in a ring shape. The n-side electrode 31 is formed on the inner side of the ring. The two ends of the S-shaped feedback waveguide 57 are disposed so that they overlap with the ring-shaped semiconductor layer.

Counterclockwise light in the ring laser is coupled to the feedback waveguide 57, and is fed back to the light emitting portion as clockwise light. On the other hand, there is virtually no clockwise light coupled to the feedback waveguide 57. Therefore, the clockwise loop mode is given priority.

In the light receiving element (pin-PD) 24 illustrated in FIGS. 5A and 5B, the light propagated through the optical waveguide 61 is evanescently coupled.

As illustrated in FIG. 5B, the coupling length is increased by folding back the optical waveguide 61 at the pin-PD, so it is possible to increase the coupling efficiency. Also, by providing the final terminal of the optical waveguide 61 with the tapered shape, the residual light can be dispersed, and reflection and returning of light can be prevented.

Also, a membrane reflector photo diode (MR-PD) can be used as the light receiving element 24 instead of the evanescent link pin-PD.

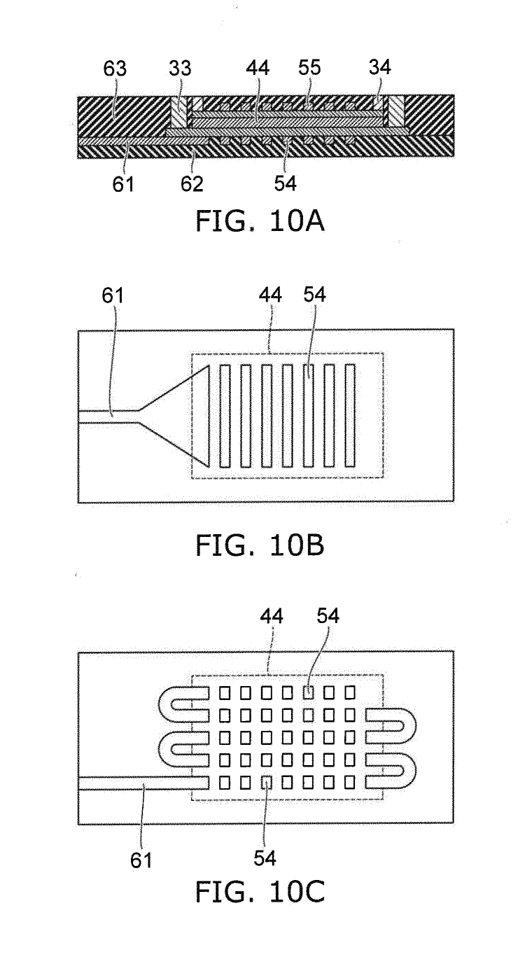

FIG. 10A is a schematic cross-sectional view of the MR-PD, and FIG. 10B is a schematic plan view of the MR-PD.

HCG resonance occurs at a specific wavelength in a lower HCG coupler 54 and an upper HCG mirror 55. Also, the HCG coupling MR-PD may have the lower HCG coupler 54 only, without the upper HCG mirror 55.

In the HCG resonance/coupling MR-PD, the optical waveguide 61 may be a single pass (high coupling efficiency HCG), or it may be repeated (low coupling efficiency HCG) as illustrated in FIG. 10C.

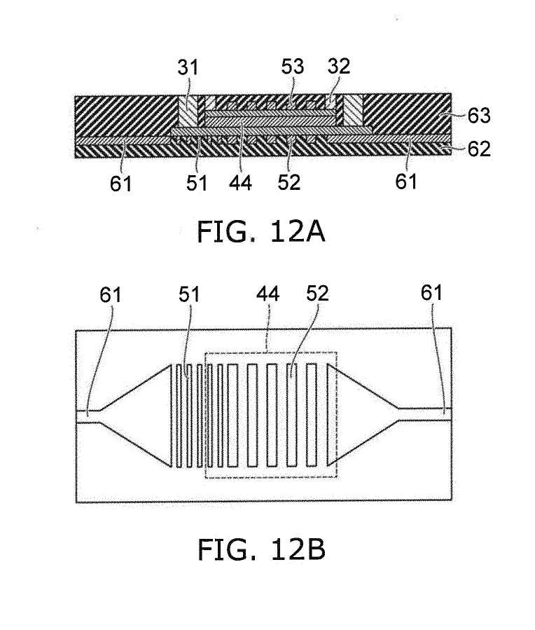

FIG. 12A is a schematic cross-sectional view illustrating another example of the MR-VCSEL, and FIG. 12B is a schematic plan view of the MR-VCSEL.

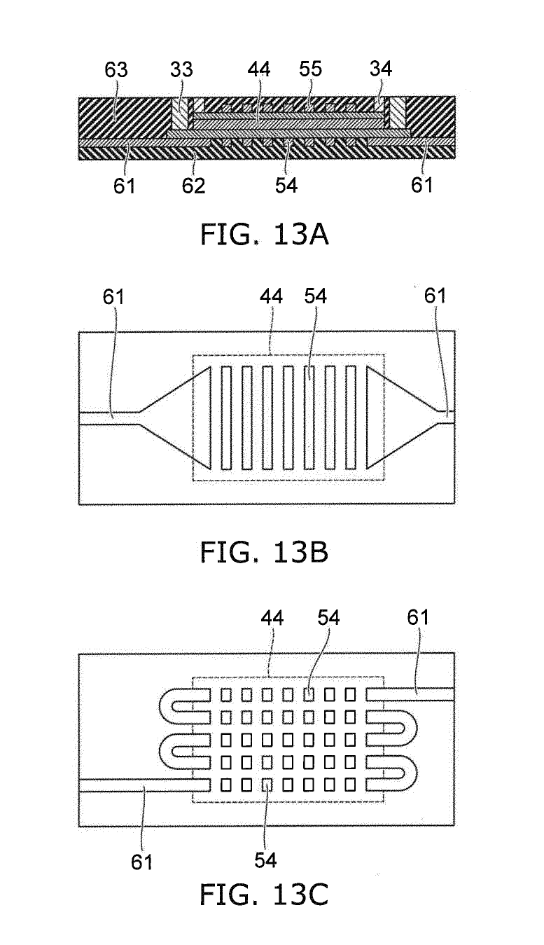

FIG. 13A is a schematic cross-sectional view of another example of the MR-PD, and FIGS. 13B and 13C are schematic plan views of the MR-PD.

In the examples illustrated in FIGS. 12A to FIG. 13C, by connecting the MR-VCSEL with a through waveguide and the MR-PD, which have different operating wavelengths, in a cascade, the signals from different terminals are transmitted and received on different wavelengths, so it is possible to connect a plurality of signals in a single optical waveguide 61 by wavelength division multiplexing (WDM).

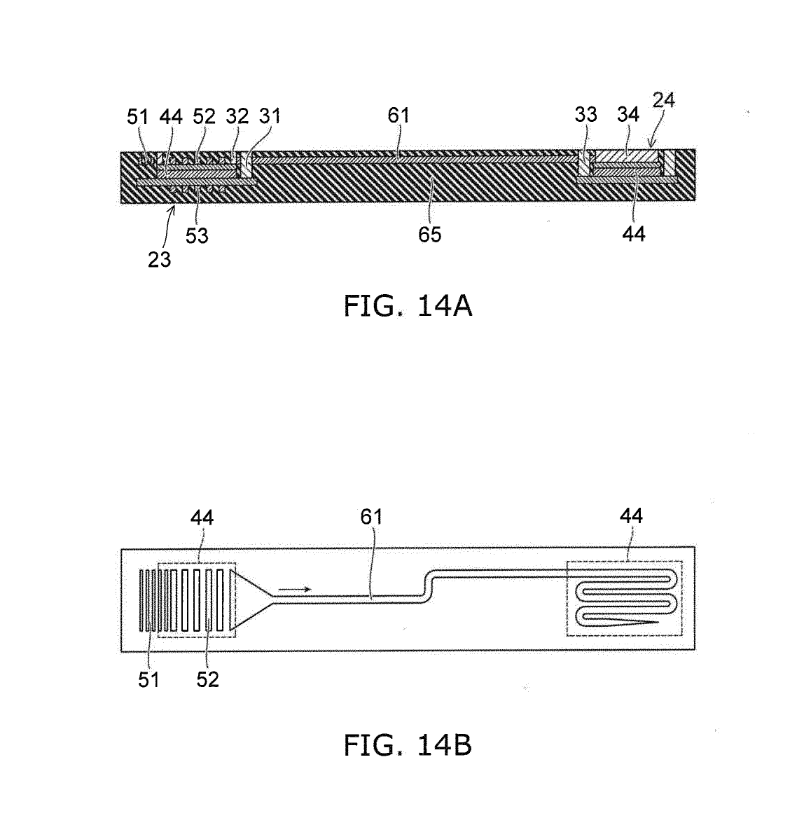

FIG. 14A is a schematic cross-sectional view of an optical interconnection structure with a top waveguide format, and FIG. 14B is a schematic plan view of the optical interconnection structure.

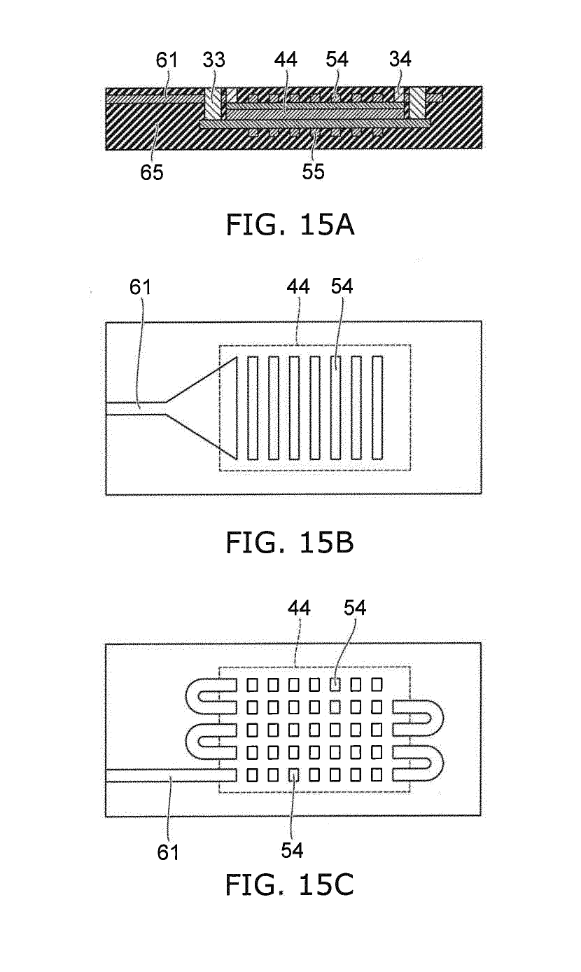

FIG. 15A is a schematic cross-sectional view of another example of light receiving element (MR-PD) with a top waveguide format, and FIG. 15B is a schematic plan view of the MR-PD. FIG. 15C is a schematic plan view of a foldback type MR-PD.

With the top waveguide format, the optical waveguide 61 is formed at the same time as the upper HCG 52 is formed, and not at the same time as the lower HCG 53 is formed. In other words, the optical waveguide 61 and the upper HCG 52 are formed at the same time, by patterning the same silicon film.

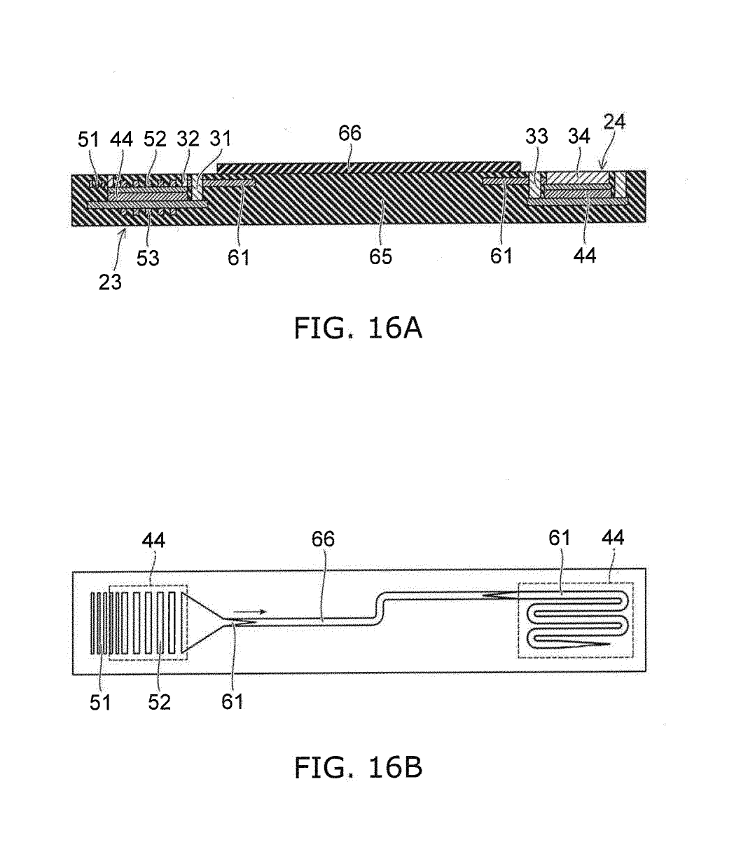

With the top waveguide format, the optical waveguide 61 can be formed later, so as illustrated in FIGS. 16A and 16B, the optical devices 23, 24 can be arranged in advance, .and the optical waveguide pattern can be formed as a semifinished optical interconnection structure that is formed later.

FIG. 16A is a schematic cross-sectional view of another example of an optical interconnection structure with a top waveguide format, and FIG. 16B is a schematic plan view of the optical interconnection structure.

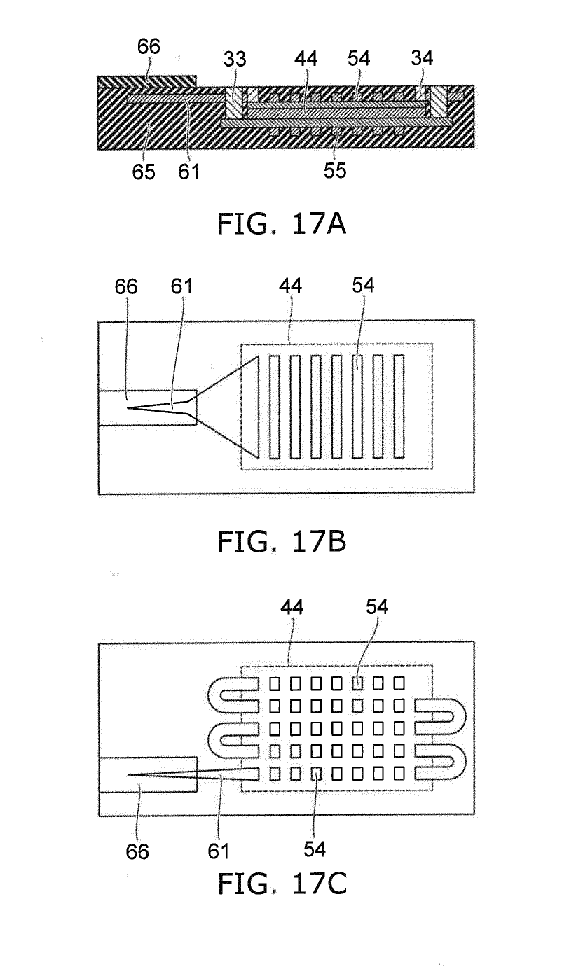

FIG. 17A is a schematic cross-sectional view of another example of light receiving element (MR-PD) with a top waveguide format, and FIG. 17B is a schematic plan view of the MR-PD. FIG. 17C is a schematic plan view of a foldback type MR-PD.

In this example, after forming the light emitting element 23, the light receiving element 24, and the short throw silicon optical waveguide 61 optically coupled to the light emitting element 23 and the light receiving element 24, a resin optical waveguide 66 is formed. Both ends of the resin optical waveguide 66 overlap with and are optically coupled to the silicon waveguide (optical coupler) 61 via the insulating film. Low loss is enabled by replacing the optical interconnection with the resin optical waveguide 66 part way.

After forming the lower HCG 53, attaching the optical device material, and processing the optical device material, the silicon film (amorphous silicon film or polysilicon film) is formed. Then, the silicon film is patterned, and the upper HCG 52 of the light emitting element (MR-VCSEL) 23, the DBR 51, and the short throw (for example, length 400 μm) optical waveguide (optical coupler) 61 with a tapered tip are formed.

The following is a description of another embodiment. The same reference signs are given to elements that are the same as the above embodiment, and detailed descriptions thereof are omitted.

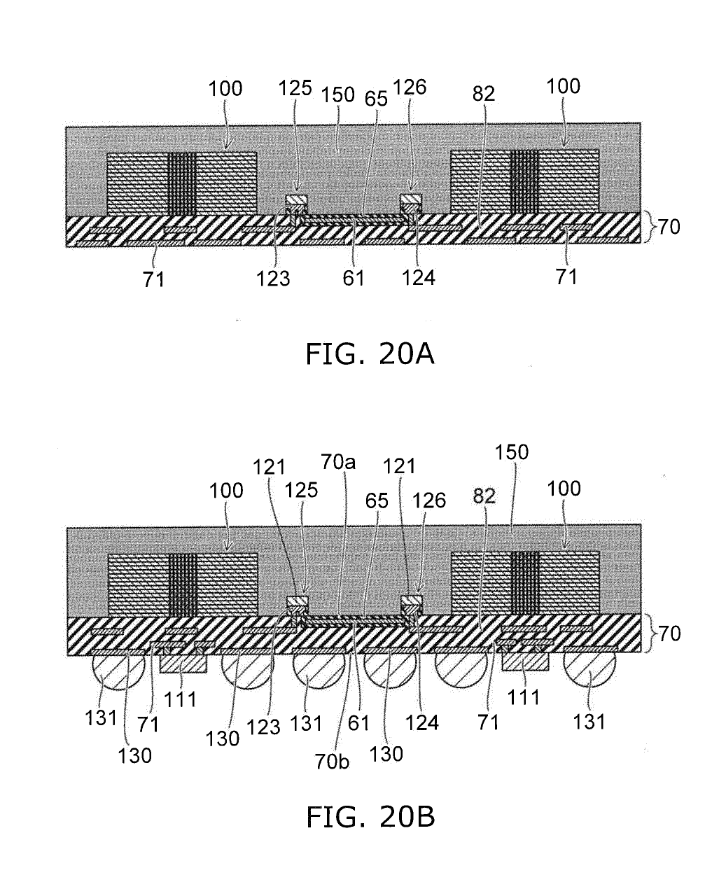

FIG. 20B is a schematic cross-sectional view of an optoelectronic integrated semiconductor module according to another embodiment.

The optoelectronic integrated semiconductor module illustrated in FIG. 20B includes the electric interconnection layer 70, the plurality of semiconductor devices 100 mounted on the electric interconnection layer 70, and the resin 150 that seals the semiconductor devices 100.

The electric interconnection layer 70 includes the metal interconnection 71 and the insulating film 82. The metal interconnection 71 is, for example, copper interconnection, and the insulating film 82 insulates between the metal interconnection 71.

The semiconductor devices 100 are mounted on the first face 70a of the electric interconnection layer 70, and are electrically connected to the metal interconnection 71. The plurality of external connection terminals 130 electrically connected to the metal interconnection 71 is provided on the second face 70b of the electric interconnection layer 70. The external connection terminals 130 are, for example, pad electrodes. For example, solder balls 131 or the like can be bonded to the external connection terminals 130.

Also, a semiconductor device 111 is mounted on the second face 70b of the electric interconnection layer 70. The semiconductor device 111 is electrically connected to the metal interconnection 71. For example, the semiconductor devices 100 include a memory chip, and the semiconductor device 111 includes a control circuit that controls the memory chip.

The optical waveguide 61 is provided on the first face 70a of the electric interconnection layer 70. An insulating film 65 that functions as cladding covers the top of the optical waveguide 61 provided on the first face 70a of the electric interconnection layer 70. In the example illustrated in FIG. 20B, the optical waveguide 61 is provided within the insulating film 65 that functions as cladding provided on the first face 70a of the electric interconnection layer 70. The interlayer insulating film 82 of the electric interconnection layer 70 can also serve as cladding below the optical waveguide 61.

Optical devices are mounted on the first face 70a of the electric interconnection layer 70. The optical devices include the light emitting element 23 and the light receiving element 24. The light emitting element 23 and the light receiving elements 24 are electrically connected to the metal interconnection 71, and are optically coupled to the optical waveguide 61. In the optoelectronic integrated semiconductor module also, for example, a portion of the signal line between the external connection terminals 130 and the semiconductor device 111 is an optical interconnection.

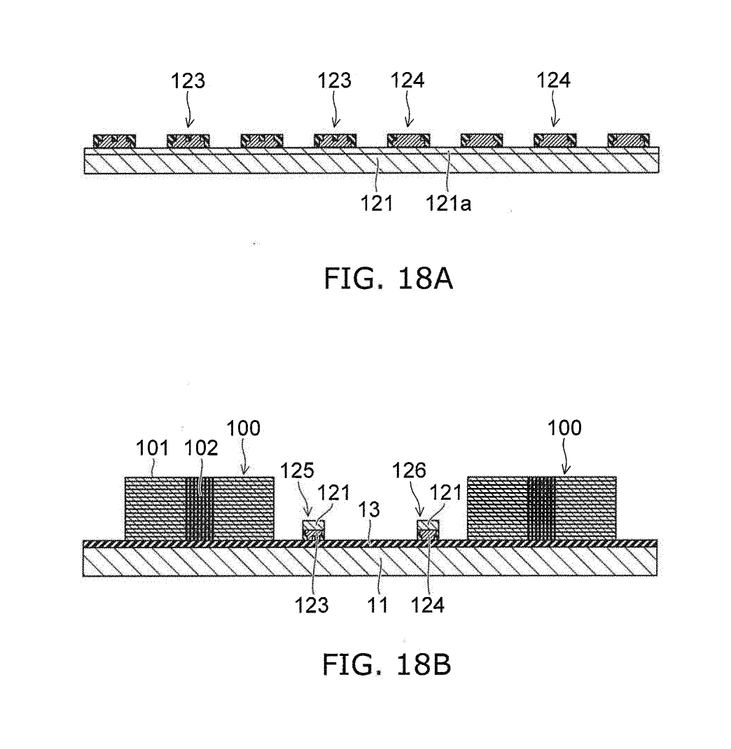

Next, a method for manufacturing the optoelectronic integrated semiconductor module illustrated in FIG. 20B is described with reference to FIG. 18A to FIG. 20B.

As illustrated in FIG. 18A, a light emitting element 123 and a light receiving element 124 are formed on a silicon substrate 121. An optical device driving IC (semiconductor integrated circuit) 121a is formed on a surface of the silicon substrate 121.

A process for forming the optical devices (light emitting element 123 and light receiving element 124) includes a process of attaching optical device material (for example, a group III-V compound semiconductor epitaxial growth layer) to the silicon substrate 121. The optical device material is attached to the silicon substrate 121 either in wafer form or in the form of chips separated into individual pieces.

The optical device material is directly bonded to the silicon substrate 121. Alternatively, the optical device material can be bonded to the silicon substrate 121 via an oxide film or an adhesive layer. Also, the optical device material may be formed by epitaxial growth on the silicon substrate 121.

Then, processing of the optical device material and forming of electrodes and the like are performed on the silicon substrate 121, and the plurality of light emitting elements 123 and light receiving elements 124 are formed on the silicon substrate 121 in wafer form.

Then, the silicon substrate 121 is diced, to produce a plurality of chips separated into individual pieces. The chips that include the silicon substrate and that has been separated into individual pieces include at least one light emitting element 123, or at least one light receiving element 124.

These optical device chips with substrate 125, 126 are temporarily bonded to the support member 11, as illustrated in FIG. 18B. The optical device chip with substrate 125 has a structure in which the silicon substrate 121 and the light emitting element 123 are integrated, and the optical device chip with substrate 126 has a structure in which the silicon substrate 121 and the light receiving element 124 are integrated.

In a case where the optical device driving IC 121a is formed on the silicon substrate 121, the optical devices 123, 124 are integrated with the substrate that includes the driving IC.

The support member 11 is, for example, a silicon substrate, a glass substrate, a resin substrate, or the like, and an organic or inorganic temporary bonding member 13 is formed on a surface of the support member 11. The optical device chips 125, 126 are bonded to the temporary bonding member 13.

In addition, the plurality of semiconductor devices 100 is bonded to the temporary bonding member 13. The semiconductor device 100 has a three-dimensional integrated LSI structure in which a plurality of semiconductor chips (for example, memory chips) 101 is stacked. The plurality of semiconductor chips 101 is connected using through electrodes 102 such as TSVs.

A stacked body including the stacked semiconductor chips 101 connected by TSVs may be bonded to the support member 11, or a stacked body including the stacked chips is integrated may be formed by successively stacking thin chips with TSVs onto the support member 11.

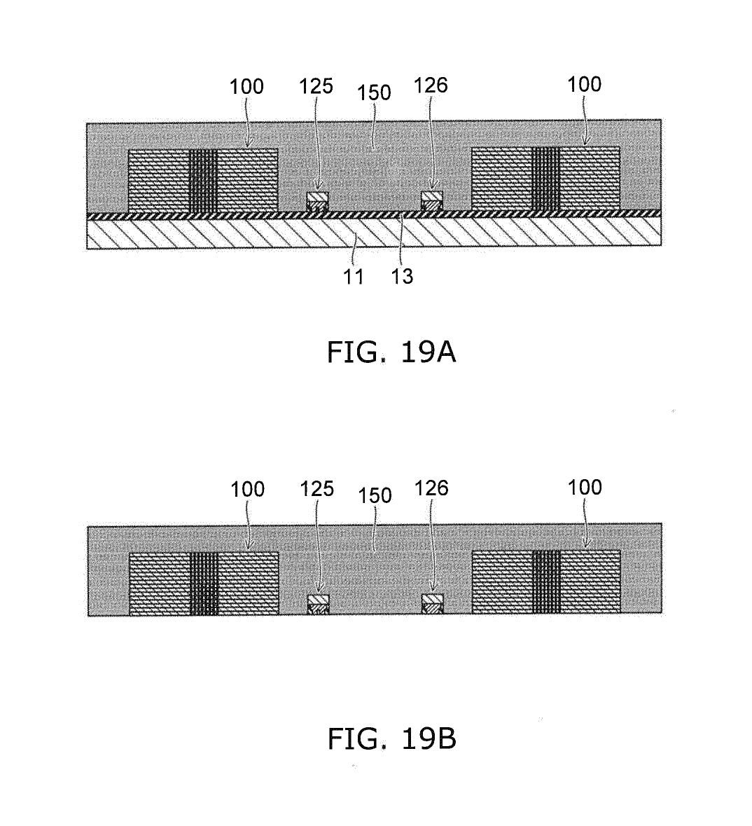

After the optical device chips with substrate 125, 126 and the semiconductor devices 100 have been bonded to the support member 11, the optical device chips with substrate 125, 126 and the semiconductor devices 100 are sealed with mold resin 150, as illustrated in FIG. 19A. The resin 150 covers the optical device chips with substrate 125, 126 and the semiconductor devices 100.

After forming the resin 150, the support member 11 is removed. For example, a knife edge is inserted into the temporary bonding member 13, and the support member 11 is mechanically peeled. Also, the temporary bonding member 13 can be heated and foamed to separate the support member 11. Also, the temporary bonding member 13 can be separated from the support member 11 by irradiating it with a laser to degrade it. Also, the support member 11 may be removed by grinding or selectively etching, or the like.

After the support member 11 is removed, a device/chip arrangement face of the structural body in which the optical device chips with substrate 125, 126 and the semiconductor devices 100 are integrated with the resin 150 is exposed.

The exposed device/chip arrangement face forms an optical interconnection/electrical interconnection structure, as illustrated in FIG. 20A. For example, the first the optical waveguide (core) 61 that optically couples the light emitting element 123 and the light receiving element 124, and the insulating film (cladding) 65 are formed.

The optical waveguide 61 is formed from, for example, an inorganic material (Si, SiON, or the like), or an organic material (a resin such as silicone, epoxy, and polyimide).

Next the metal interconnection 71 either as a single layer or multiple layers, and an interlayer insulating film 82 are formed. The metal interconnection 71 is, for example, Cu interconnection, formed by a semi-additive method. The interlayer insulating film 82 is, for example, a polyimide resin, an epoxy resin, a silicone resin, or the like. The interlayer insulating film 82 may also serve as the cladding 65 on the lower side of the optical waveguide (core) 61 in FIG. 20A.

The semiconductor devices 100 are electrically connected to the metal interconnection 71. The light emitting element 123 and the light receiving element 124 are electrically connected to the metal interconnection 71, and are optically coupled to the optical waveguide 61.

Then, the plurality of external connection terminals 130 (for example, pad electrodes) is formed, as illustrated in FIG. 20B. Also, additional metal interconnection 71 may be formed on the electric interconnection layer 70. Solder balls 131 or the like may be formed on the external connection terminals 130.

Semiconductor devices (controller chip, interface chip, and the like) 111 that are separate from the semiconductor devices 100 on the first face 70a are mounted on the second face 70b of the electric interconnection layer 70. Also, passive components such as condensers may also be mounted on a portion of the second face 70b of the electric interconnection layer 70. Also, transparent optical connection terminals (for example, silicone resin balls or the like) 132 may be formed on the second face 70b of the electric interconnection layer 70, as illustrated in FIG. 28.

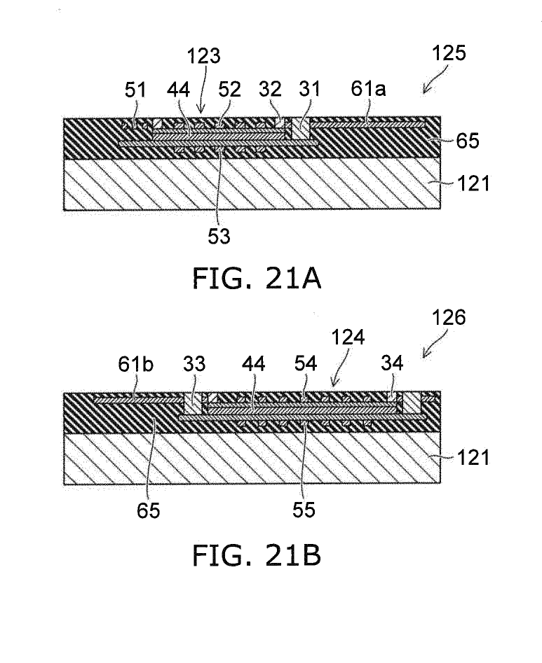

FIG. 21A is a schematic cross-sectional view of an example of optical device chip 125 with substrate.

FIG. 21B is a schematic cross-sectional view of an example of optical device chip 126 with substrate.

The optical device chip with substrate 125 illustrated in FIG. 21A has the same structure as the top waveguide format optical device illustrated in FIG. 16A, as described previously.

In other words, the optical device chip with substrate 125 includes the light emitting element (MR-VCSEL) 123 and the short throw optical waveguide (optical coupler) 61a optically coupled to the light emitting element 123, on the silicon substrate 121.

The optical device chip with substrate 126 illustrated in FIG. 21B has the same structure as the top waveguide format optical device illustrated in FIG. 17A, as described previously.

In other words, the optical device chip with substrate 126 includes the light receiving element (MR-PD) 124 and the short throw optical waveguide (optical coupler) 61b optically coupled to the light receiving element 124, on the silicon substrate 121.

The optical waveguides (optical couplers) 61a, 61b are optically coupled to the optical waveguide 61 illustrated in FIG. 20B.

In the embodiment as illustrated in FIG. 18A to FIG. 21B also, a high-speed connection with an optical interconnection and power supply/low speed connection with the metal interconnection can be configured from low cost resin mold as the basis. A high cost mounting substrate such as a silicon interposer with TSVs is not used, so low cost can be easily achieved with high function. Also, a large scale panel level batch forming process in the order of meters is enabled, for example, large scale semiconductor modules of 5 cm×5 cm or larger can be easily mass-produced, so high performance low cost large scale optoelectronic integrated semiconductor modules can be realized.

Also, solder balls or Au stud bumps are not used for mounting the semiconductor devices 100 and the optical device chips with substrate 125, 126, so these devices/chips can be arranged at high speed, which enables cost reduction.

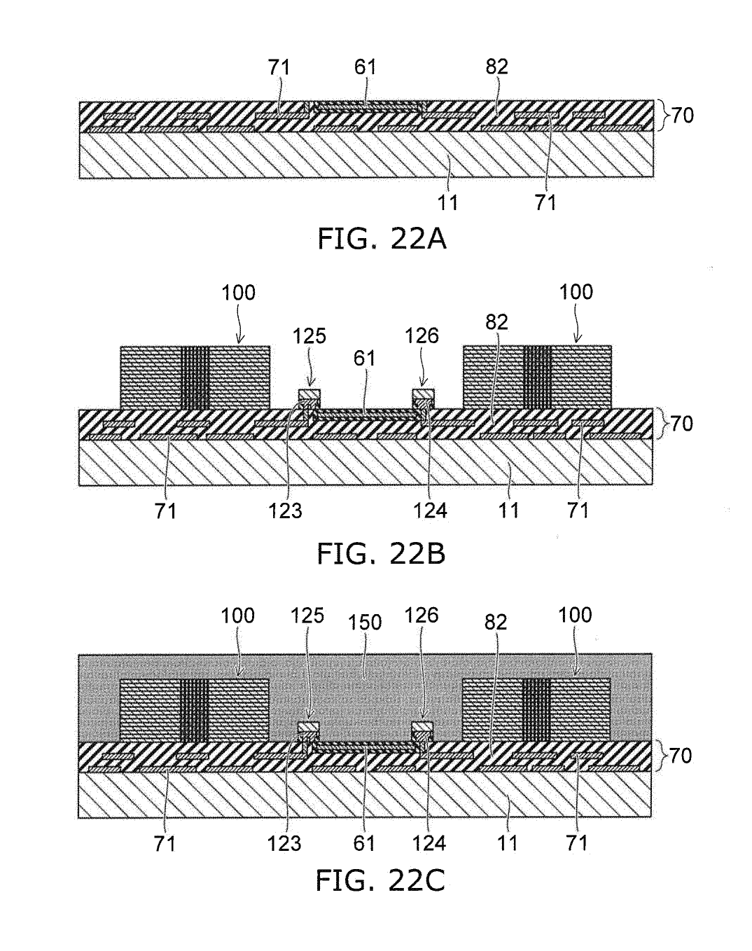

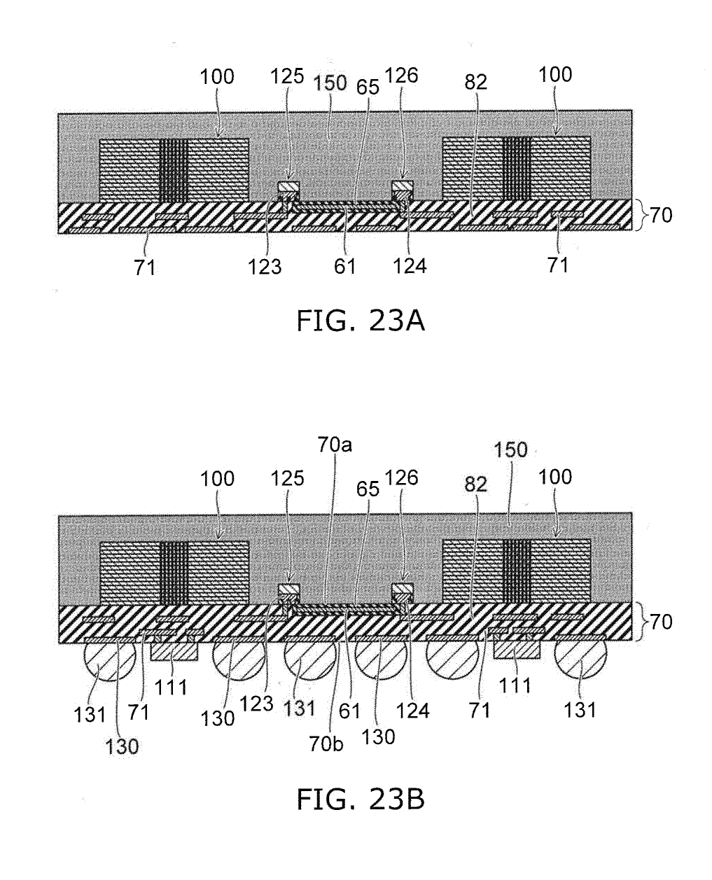

Next, another method for manufacturing the optoelectronic integrated semiconductor module illustrated in FIG. 20B is described with reference to FIG. 22A to FIG. 23B.

As illustrated in FIG. 22A, the electric interconnection layer 70 partially replaced with an optical interconnection is formed on the support member 11. The metal interconnection 71 either as a single layer or multiple layers, and the interlayer insulating film 82 are formed. In addition, the optical waveguide 61 is formed on a surface side of the electric interconnection layer 70.

As illustrated in FIG. 22B, the plurality of semiconductor devices 100 and the optical device chips with substrate 125, 126 are mounted on the electric interconnection layer 70.

As illustrated in FIG. 18A, the optical device chips with substrate 125, 126 are obtained by dicing the silicon substrate 121 after forming the light emitting element 123 and the light receiving element 124 on the silicon substrate 121, the same as for the embodiment described previously.

The electrical terminals of the optical device chips with substrate 125, 126 are electrically connected to the metal interconnection 71. The optical waveguides (optical couplers) 61a, 61b as illustrated in FIGS. 21A and 21B of the optical device chips with substrate 125, 126 are optically coupled to the optical waveguide 61.

The semiconductor devices 100 are electrically microbump-connected to the metal interconnection 71 by, for example, reflow connection with small solder balls, or ultrasonic bonding using Au stud bumps.

After the optical device chips with substrate 125, 126 and the semiconductor devices 100 have been mounted on the electric interconnection layer 70, the optical device chips with substrate 125, 126 and the semiconductor devices 100 are sealed with mold resin 150, as illustrated in FIG. 22C. The resin 150 covers the optical device chips with substrate 125, 126 and the semiconductor devices 100.

After forming the resin 150, the support member 11 is removed. For example, a knife edge is inserted into a temporary bonding member formed at the boundary between the support member 11 and the electric interconnection layer 70, and the support member 11 is mechanically peeled. Also, the temporary bonding member can be heated and foamed to separate the support member 11. Also, the temporary bonding member can be separated from the support member 11 by irradiating the temporary bonding member with a laser to be degraded. Also, the support member 11 may be removed by grinding or selectively etching, or the like.

When the support member 11 is removed, the second face of the electric interconnection layer 70 is exposed, as illustrated in FIG. 23A. The plurality of external connection terminals (for example, pad electrodes) is formed on the second face of the electric interconnection layer 70, as illustrated in FIG. 23B. Solder balls 131 or the like may be formed on the external connection terminals 130. Also, additional metal interconnection 71 may be formed on the electric interconnection layer 70.

Semiconductor devices (controller chip, interface chip, and the like) 111 that are separate from the semiconductor devices 100 on the first face 70a are mounted on the second face 70b of the electric interconnection layer 70. Also, passive components such as condensers may also be mounted on a portion of the second face 70b of the electric interconnection layer 70. Also, transparent optical connection terminals (for example, silicone resin balls or the like) 132 may be formed on the second face 70b of the electric interconnection layer 70, as illustrated in FIG. 28.

In the embodiment as illustrated in FIG. 22A to FIG. 23B also, a high-speed connection with an optical interconnection and power supply/low speed connection with the metal interconnection can be configured from low cost resin mold as basis. A high cost mounting substrate such as a silicon interposer with TSVs is not used, so low cost can be easily achieved with high function. Also, a large scale panel level batch forming process in the order of meters is enabled, for example, large scale semiconductor modules of 5 cm×5 cm or larger can be easily mass-produced, so high performance low cost large scale optoelectronic integrated semiconductor modules can be realized.

Also, the optical device chips with substrate 125, 126 and the semiconductor devices 100 are mounted on the electric interconnection layer 70 using solder or metal bumps, so the positional deviation of the devices/chips in resin molding is small, and high density interconnection is easily formed using very fine metal interconnection.

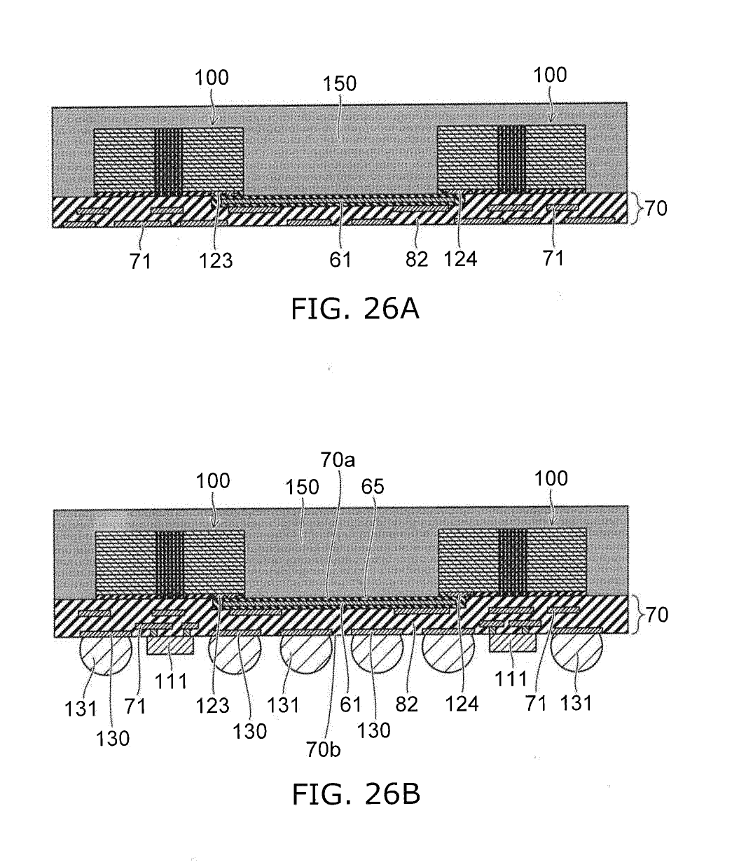

FIG. 26B is a schematic cross-sectional view of an optoelectronic integrated semiconductor module according to yet another embodiment.

The optoelectronic integrated semiconductor module illustrated in FIG. 26B includes the electric interconnection layer 70, the plurality of semiconductor devices 100 mounted on the electric interconnection layer 70, and the resin 150 that seals the semiconductor devices 100.

The electric interconnection layer 70 includes the metal interconnection 71 and the insulating film 82. The metal interconnection 71 is, for example, copper interconnection, and the insulating film 82 insulates between metal interconnection 71.

The semiconductor devices 100 are mounted on the first face 70a of the electric interconnection layer 70, and are electrically connected to the metal interconnection 71. A plurality of external connection terminals 130 electrically connected to the metal interconnection 71 is provided on the second face 70b of the electric interconnection layer 70. The external connection terminals 130 are, for example, pad electrodes. For example, solder balls 131 or the like can be bonded to the external connection terminals 130.

Also, the semiconductor device 111 is mounted on the second face 70b of the electric interconnection layer 70. The semiconductor device 111 is electrically connected to the metal interconnection 71. For example, the semiconductor devices 100 include a memory chip, and the semiconductor device 111 includes a control circuit that controls the memory chip.

The optical waveguide 61 is provided on the first face 70a of the electric interconnection layer 70. The optical waveguide 61 is provided within the insulating film 65 provided on the first face 70a of the electric interconnection layer 70.

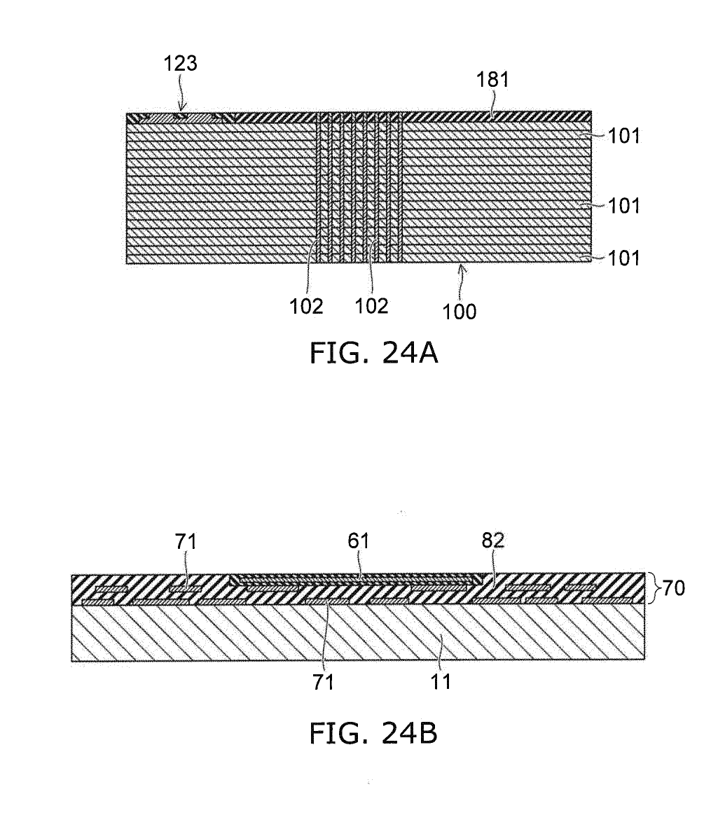

FIG. 24A is a schematic enlarged cross-sectional view of the semiconductor device 100.

The semiconductor device 100 has a three-dimensional integrated LSI structure in which a plurality of semiconductor chips (for example, memory chips) 101 is stacked. The plurality of semiconductor chips 101 is connected using through electrodes 102 such as TSVs.

An optical device is integrated on a first face of the semiconductor device 100. In FIG. 24A, the light emitting element 123 is illustrated as an example of optical device. An insulating film 181 is formed over the region of the first face of the semiconductor device 100 apart from that region where optical devices are integrated.

The optical devices include the light emitting element 123 and the light receiving element 124. As illustrated in FIG. 26B, the semiconductor device 100 into which the light emitting element 123 is integrated and the semiconductor device 100 into which the light receiving element 124 is integrated are mounted on the first face 70a of the electric interconnection layer 70.

The light emitting element 23 and the light receiving elements 24 are electrically connected to the metal interconnection 71, and are optically coupled to the optical waveguide 61. In the optoelectronic integrated semiconductor module also, for example, a portion of the signal line between the external connection terminals 130 and the semiconductor device 111 is an optical interconnection.

Next, a method for manufacturing the optoelectronic integrated semiconductor module illustrated in FIG. 26B is described with reference to FIG. 24A to FIG. 26B.

The metal interconnection 71 either as a single layer or multiple layers, and the interlayer insulating film 82 are formed on the support member 11, as illustrated in FIG. 24B. In addition, the optical waveguide 61 is formed on the first face of the electric interconnection layer 70.

The semiconductor devices 100 with optical devices are mounted on the first face of the electric interconnection layer 70, as illustrated in 25A. The first face of the semiconductor device 100 with optical devices illustrated in FIG. 24A on which the optical devices are integrated and on which the insulating film 181 is formed faces toward the first face of the electric interconnection layer 70. The semiconductor device 111 as previously described may be embedded in the insulating film 181.

The electrical terminals of the optical devices 123, 124 are electrically connected to the metal interconnection 71. The optical waveguides (optical couplers) 61a, 61b as illustrated in, for example, FIGS. 21A and 21B of the optical devices 123, 124 are optically coupled to the optical waveguide 61.

The semiconductor devices 100 are electrically microbump-connected to the metal interconnection 71 by, for example, reflow connection with small solder balls, or ultrasonic bonding using Au stud bumps.

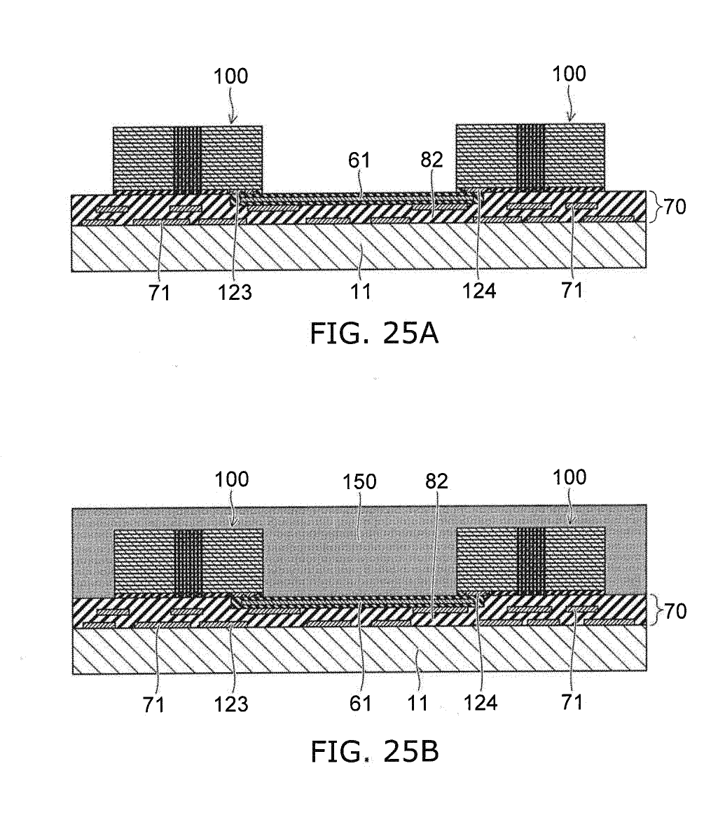

After the semiconductor devices 100 with optical devices are mounted on the first face of the electric interconnection layer 70, the semiconductor devices 100 with optical devices are sealed with the mold resin 150, as illustrated in FIG. 25B. The resin 150 covers the semiconductor devices 100 with optical devices.

After forming the resin 150, the support member 11 is removed. For example, a knife edge is inserted into a temporary bonding member formed at the boundary between the support member 11 and the electric interconnection layer 70, and the support member 11 is mechanically peeled. Also, the temporary bonding member can be heated and foamed to separate the support member 11. Also, the temporary bonding member can be separated from the support member 11 by irradiating the temporary bonding member with a laser to be degraded. Also, the support member 11 may be removed by grinding or selectively etching, or the like.

When the support member 11 is removed, the second face of the electric interconnection layer 70 is exposed, as illustrated in FIG. 26A. The plurality of external connection terminals (for example, pad electrodes) is formed on the second face of the electric interconnection layer 70, as illustrated in FIG. 26B. Solder balls 131 or the like may be formed on the external connection terminals 130. Also, additional metal interconnection 71 may be formed on the electric interconnection layer 70.

Semiconductor devices (controller chip, interface chip, and the like) 111 that are separate from the semiconductor devices 100 on the first face 70a are mounted on the second face 70b of the electric interconnection layer 70. Also, passive components such as condensers or the like may also be mounted on a portion of the second face 70b of the electric interconnection layer 70. Also, transparent optical connection terminals (for example, silicone resin balls or the like) 132 may be formed, as illustrated in FIG. 28.

In the embodiment as illustrated in FIG. 24A to FIG. 26B also, a high-speed connection with an optical interconnection and power supply/low speed connection with the metal interconnection can be configured from low cost resin mold as basis. A high cost mounting substrate such as a silicon interposer with TSVs is not used, so low cost can be easily achieved with high function. Also, a large scale panel level batch forming process in the order of meters is enabled, for example, large scale semiconductor modules of 5 cm×5 cm or larger can be easily mass-produced, so high performance low cost large scale optoelectronic integrated semiconductor modules can be realized.

Also, the optical devices 123, 124 and the semiconductor devices 100 are mounted on the first face of the electric interconnection layer 70 using solder or metal bumps, so the positional deviation of the devices/chips in resin molding is small, and high density interconnection is easily formed using very fine metal interconnection.

Also, optical connection to the optical waveguide 61 with low signal degradation from the semiconductor devices 100 such as LSI is enabled, so extremely high quality high speed high density interconnection is possible. An optical device driving circuit is formed in the semiconductor device 100 into which the optical devices are integrated. Therefore, impedance matching interconnection which is necessary when the optical device driving circuit is mounted as a separate IC is not required, and the load resistance for impedance matching is not necessary. This enables major reduction in the electrical power consumption due to the reduction in the electrical power consumed by the load resistance and the like.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. An optoelectronic integrated semiconductor module, comprising:
an electric interconnection layer including a metal interconnection and an insulating film;
an optical device provided within the electric interconnection layer, and electrically connected to the metal interconnection, the optical device including at least one of a light emitting element and a light receiving element;
an optical waveguide provided within the electric interconnection layer, and optically coupled to the optical device;
a plurality of semiconductor devices provided on a first face of the electric interconnection layer, and electrically connected to the metal interconnection;
a resin sealing the semiconductor devices; and
a plurality of external connection terminals provided on a second face of the electric interconnection layer, and electrically connected to the metal interconnection.

2. The module according to claim 1, further comprising a transparent optical connection terminal provided on the second face of the electric interconnection layer, the optical connection terminal being optically coupled to the optical device or the optical waveguide.

3. An optoelectronic integrated semiconductor module, comprising:
an electric interconnection layer including a metal interconnection and an insulating film;
a plurality of semiconductor devices provided on a first face of the electric interconnection layer, and electrically connected to the metal interconnection;
an optical device provided on the first face of the electric interconnection layer, and electrically connected to the metal interconnection, the optical device including at least one of a light emitting element and a light receiving element;
an optical waveguide provided on the first face of the electric interconnection layer, and optically coupled to the optical device;
a resin sealing the semiconductor devices and the optical device; and
a plurality of external connection terminals provided on a second face of the electric interconnection layer, and electrically connected to the metal interconnection.

4. The module according to claim 3, wherein the optical device is integrated with a substrate including a semiconductor integrated circuit.

5. The module according to claim 3, wherein the optical device is integrated on a surface of the semiconductor devices.

6. The module according to claim 3, further comprising a transparent optical connection terminal provided on the second face of the electric interconnection layer, the optical connection terminal being optically coupled to the optical device or the optical waveguide.

7. A method for manufacturing an optoelectronic integrated semiconductor module, comprising:
forming an optical device, an optical waveguide, and an electric interconnection layer on a support member, the optical device including at least one of a light emitting element and a light receiving element, the optical waveguide being optically coupled to the optical device, the electric interconnection layer including metal interconnection and an insulating film, the electric interconnection layer covering the optical device and the optical waveguide;
mounting a plurality of semiconductor devices on a first face of the electric interconnection layer, the semiconductor devices being electrically connected to the metal interconnection;
forming resin sealing the semiconductor devices on the electric interconnection layer; and
removing the support member after forming the resin.

8. A method for manufacturing an optoelectronic integrated semiconductor module, comprising:
mounting a plurality of semiconductor devices and an optical device on a support member, the optical device including at least one of a light emitting element and a light receiving element;
forming resin sealing the semiconductor devices and the optical device on the support member;
removing the support member after forming the resin; and
forming an electric interconnection layer and an optical waveguide on a structural body after removing the support member, the structural body including the resin, the semiconductor devices and the optical device being integrated with the resin, the electric interconnection layer including a metal interconnection and an insulating film, the metal interconnection being electrically connected to the semiconductor devices and the optical device, the optical waveguide being optically coupled to the optical device.

9. A method for manufacturing an optoelectronic integrated semiconductor module, comprising:
forming an electric interconnection layer and an optical waveguide on a support member, the electric interconnection layer including a metal interconnection and an insulating film;
mounting a semiconductor device and an optical device on the electric interconnection layer, the semiconductor device being electrically connected to the metal interconnection, the optical device including at least one of a light emitting element and a light receiving element, the light emitting element being electrically connected to the metal interconnection and optically coupled to the optical waveguide, the light receiving element being electrically connected to the metal interconnection and optically coupled to the optical waveguide;
forming resin sealing the semiconductor device and the optical device on the electric interconnection layer; and
removing the support member after forming the resin.

10. The method according to claim 9, wherein the optical device is mounted on the electric interconnection layer together with the semiconductor device with the optical device integrated on a surface of the semiconductor device.
